(19) United States
(12) Patent Application Publication
(10) Pub. No.: US 2009/0294157 A1
(43) Pub. Date: Dec. 3, 2009

(54) ELECTRO-OPTIC DEVICE AND METHOD FOR MANUFACTURING THE SAME

(75) Inventors: Hyung Sup LEE, Gyeonggi-Do (KR); Young Ho KWON, Gyeonggi-Do (KR)

Correspondence Address: HOSOON LEE, 9600 SW OAK ST. SUITE 525, TIGARD, OR, 97223, US

(73) Assignees: JUSUNG ENGINEERING CO., LTD., Gyeonggi-do (KR); ADS, Gyeonggi-Do (KR)

(21) Appl. No.: 12/469,679

(22) Filed: May 21, 2009

(30) Foreign Application Priority Data
May 29, 2008 (KR) 10-2008-0050187

(51) Int. Cl. H05K 1/09; H05K 3/02

(52) U.S. Cl. 174/256; 29/847

(57) ABSTRACT

An electro-optic device includes a substrate a metal thin film pattern formed on the substrate, and a transparent electrode pattern formed to cover the metal thin film pattern, wherein one side of the metal thin film pattern is formed to be exposed to the outside of the transparent electrode pattern.

Therefore, a uniform current can flow through the transparent electrode pattern by providing a supply voltage to the metal thin film pattern and thus it is possible to manufacture the electro-optic device having uniform luminance.

### CROSS-REFERENCE TO RELATED APPLICATION

This application claims priority to Korean Patent Application No. 10-2008-0050187 filed on May 29, 2008 and all the benefits accruing therefrom under 35 U.S.C. §119, the contents of which are incorporated by reference in their entirety.

### BACKGROUND

The present disclosure relates to an electro-optic device and a method for manufacturing the same, and more particularly, to an electro-optic device and a method for manufacturing the same, capable of making a current uniformly flowing throughout a transparent electrode pattern by preventing a voltage drop of the transparent electrode pattern.

In general, an organic light emitting device includes a positive electrode, an organic material layer and a negative electrode. Herein, the positive electrode is formed using a transparent conducting material such as indium tin oxide (ITO) and indium zinc oxide (IZO). The organic material layer includes a hole injection layer, a hole transport layer, a light emitting layer, an electron transport layer and so on. According to a method of driving the organic light emitting device, if a voltage supplying unit provides a supply voltage to the positive electrode and the negative electrode, holes move from the positive electrode to the light emitting layer through the hole injection layer and the hole transport layer and electrons move from the negative electrode to the light emitting layer through the electron transport layer. These holes and electrons form electron-hole pairs in the light emitting layer, so that excitons having a high energy are formed. Then, light is emitted as the excitons drop to a bottom state of a low energy.

However, in the conventional organic light emitting device, if the supply voltage is provided to the transparent electrode, a voltage drop occurs by the resistance of the transparent electrode as become more distant from a point where the supply voltage is provided. Therefore, it is difficult to uniformly supply a current throughout the transparent electrode in a panel of more than 4 inches and thus it is impossible to manufacture a device having uniform luminance.

### SUMMARY

The present disclosure provides an electro-optic device where a current uniformly flows throughout a transparent electrode pattern regardless of a distance from a point where a supply voltage is provided by forming a metal thin film pattern connected to the transparent electrode pattern and providing the supply voltage to the metal thin film pattern, and a method for manufacturing the electro-optic device.

In accordance with an exemplary embodiment, an electro-optic device includes: a substrate; a metal thin film pattern formed on the substrate; and a transparent electrode pattern formed to cover the metal thin film pattern, wherein one side of the metal thin film pattern is formed to be exposed to the outside of the transparent electrode pattern.

In accordance with another exemplary embodiment, an electro-optic device includes: a substrate; a plurality of metal thin film patterns formed on the substrate; a plurality of transparent electrode patterns formed to intersect with the plurality of metal thin film patterns; and an insulating layer disposed between the metal thin film patterns and the transparent electrode patterns to expose portions of the metal thin film patterns.

In accordance with still another exemplary embodiment, an electro-optic device includes: a substrate; a metal thin film pattern formed on the substrate; and a transparent electrode pattern connected to a sidewall of the metal thin film pattern and corresponding to the metal thin film pattern.

The electro-optic device may further include an insulating protection layer formed on a sidewall region and an edge region of a top surface of the transparent electrode pattern or the metal thin film pattern.

The transparent electrode patterns may be connected to the metal thin film patterns through the exposed portions of the metal thin film patterns.

The plurality of metal thin film patterns may intersect with the plurality of transparent electrode patterns and one transparent electrode pattern may be connected to its corresponding metal thin film pattern at two or more points that are separated from each other.

The metal thin film pattern may have a width that is approximately 1/10 to approximately 1/100 of a width of the transparent electrode pattern.

In accordance with further another exemplary embodiment, a method for manufacturing an electro-optic device includes: forming a metal thin film pattern on a substrate; and forming a transparent electrode pattern that is connected to the metal thin film pattern using a laser scribing process.

The method may further include forming an insulating protection layer on a sidewall region and an edge region of a top surface of the transparent electrode pattern or the metal thin film pattern.

The method may further include, before forming the transparent electrode pattern, forming an insulating layer to expose a portion of the metal thin film pattern.

The metal thin film pattern may be formed using one selected from a group consisting of silver, copper, gold, magnesium, platinum, titanium and an alloy thereof, which has a solution or paste type.

The metal thin film pattern may be formed using one of a screen printing method, a pen printing method a roller printing method and a gravure printing method.

In accordance with further still another exemplary embodiment, a method for driving an electro-optic device comprising a metal thin film pattern disposed on a substrate and a transparent electrode pattern connected to the metal thin film pattern, the method comprising providing a supply voltage to a metal thin film pattern connected to a transparent electrode pattern.

a method for driving an electro-optic device includes: providing a supply voltage to a metal thin film pattern connected to a transparent electrode pattern, wherein the electro-optic device comprises the metal thin film pattern disposed over a substrate and the transparent electrode pattern connected to the metal thin film pattern.

A current may be selectively transported to the transparent electrode pattern connected to the metal thin film pattern by providing the supply voltage to the metal thin film pattern.

### BRIEF DESCRIPTION OF THE DRAWINGS

Exemplary embodiments can be understood in more detail from the following description taken in conjunction with the accompanying drawings, in which:

FIG. 1 illustrates a plan view of a transparent electrode in accordance with a first embodiment of the present invention;

FIG. 2 illustrates a cross-sectional view obtained by cutting FIG. 1 along a line A-A′;

FIGS. 3 to 6 illustrate cross-sectional views of a method for forming the transparent electrode in accordance with the first embodiment of the present invention;

FIGS. 7 to 9 illustrate cross-sectional views of a method for manufacturing an organic light emitting device in accordance with the first embodiment of the present invention;

FIG. 10 illustrates a plan view of a transparent electrode in accordance with a second embodiment of the present invention;

FIG. 11 illustrates a cross-sectional view obtained by cutting FIG. 10 along a line B-B′;

FIGS. 12 to 16 illustrate cross-sectional views of a method for forming the transparent electrode in accordance with the second embodiment of the present invention;

FIG. 17 illustrates a plan view of a transparent electrode in accordance with a third embodiment of the present invention;

FIG. 18 illustrates a cross-sectional view obtained by cutting FIG. 17 along a line C-C′;

FIGS. 19 to 22 illustrate cross-sectional views of a method for forming the transparent electrode in accordance with the third embodiment of the present invention; and

FIGS. 23 to 25 illustrate cross-sectional views of a method for manufacturing an organic tight emitting device in accordance with the third embodiment of the present invention.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, like reference numerals refer to like elements throughout.

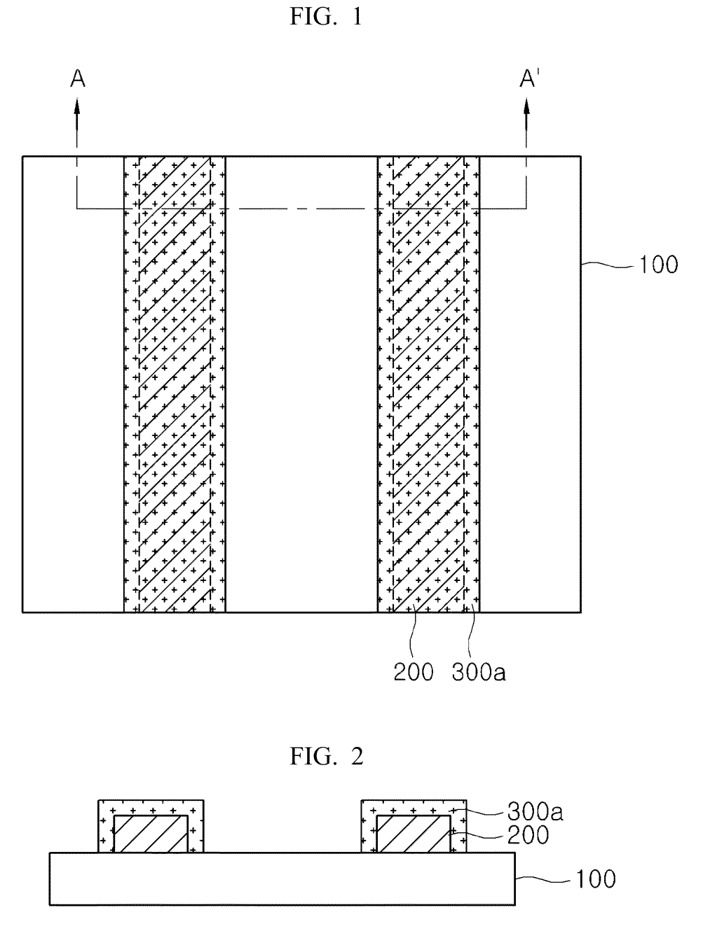

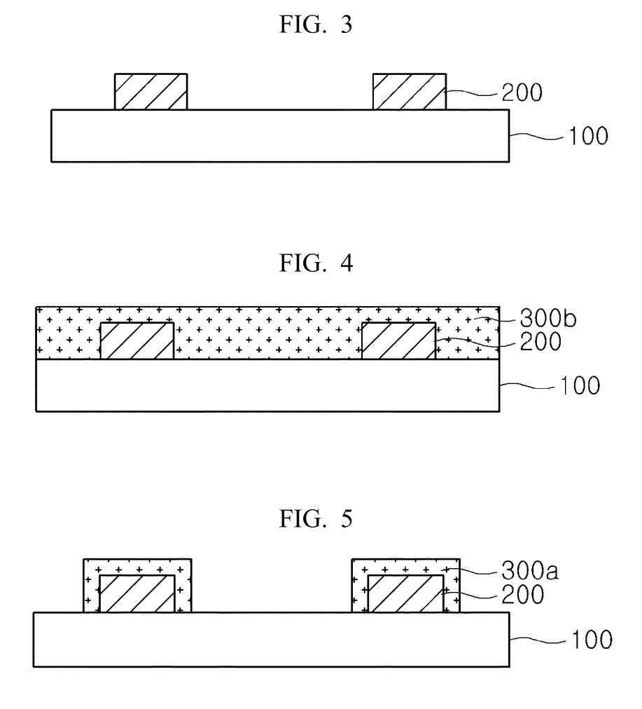

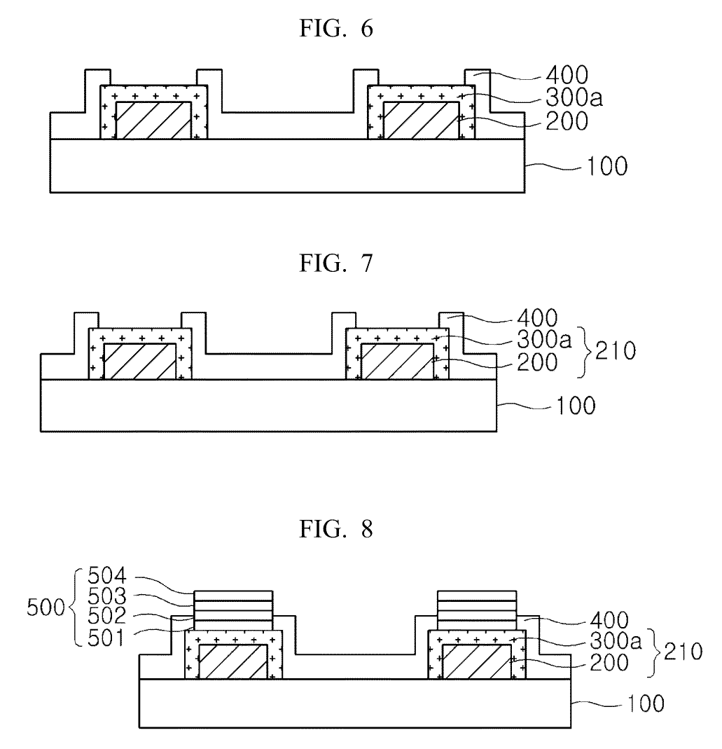

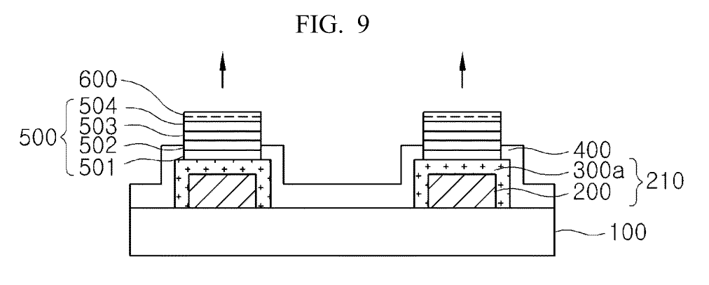

FIG. 1 illustrates a plan view of a transparent electrode in accordance with a first embodiment of the present invention. FIG. 2 illustrates a cross-sectional view obtained by cutting FIG. 1 along a line A-A′. FIGS. 3 to 6 illustrate cross-sectional views of a method for forming the transparent electrode in accordance with the first embodiment of the present invention. FIGS. 7 to 9 illustrate cross-sectional views of a method for manufacturing an organic light emitting device in accordance with the first embodiment of the present invention.

Referring to FIGS. 1 and 2, the transparent electrode includes a metal thin film pattern 200 formed on a substrate 100 and a transparent electrode pattern 300a formed to cover the metal thin film pattern 200. Herein, the metal thin film pattern 200 plays a role of making a current uniformly flow throughout the transparent electrode pattern 300a. For this purpose, in this embodiment, the metal thin film pattern 200 is formed to be disposed under the transparent electrode pattern 300a. The transparent electrode pattern 300a is formed to have a width greater than that of the metal thin film pattern 200 and the transparent electrode pattern 300a is formed to cover the metal thin film pattern 200. Furthermore, one side of the metal thin film pattern 200 is exposed to the outside of the transparent electrode pattern 300a so that a supply voltage is provided to the metal thin film pattern 200.

In the prior art, the transparent electrode pattern 300a is formed on the substrate 100 and the supply voltage is directly provided to the transparent electrode pattern 300a. However, in this embodiment, the metal thin film pattern 200 having low resistance is disposed under the transparent electrode pattern 300a so that the current uniformly flows throughout the transparent electrode pattern 300a. That is, when providing the supply voltage to one side of the metal thin film pattern 200 formed under the transparent electrode pattern 300a, the current flows along the metal thin film pattern 200 having the low resistance and the current is transported to the transparent electrode pattern 300a disposed over the metal thin film pattern 200. Through this, the current uniformly flows throughout the transparent electrode pattern 300a regardless of the distance from a point where the supply voltage is provided.

FIGS. 3 to 6 describe the method for forming the transparent electrode in accordance with the first embodiment of the present invention.

Referring to FIG. 3, the metal thin film pattern 200 is formed over the substrate 100. Herein, the substrate 100 may use one of a plastic substrate such as PE, PES and PEN, and a glass substrate, which has light permeability that is equal to or higher than 80%. The metal thin film pattern 200 is formed through a screen printing method. Although it is not shown, after disposing a mask having a desired pattern, i.e., a stencil mask opening a region where the metal thin film pattern 200 is to be formed, on the substrate 100, a metal thin film forming material having a paste or solution type is coated on the stencil mask. The metal thin film forming material is coated on a portion of the substrate 100 that is exposed by the stencil mask by moving the metal thin film forming material on the stencil mask using a squeeze. Herein, the metal thin film forming material having the paste or solution type is made by mixing metal nano particles having a particle size of approximately 3 nm to approximately 6 nm and an organic solvent. The metal nano particle may include one of silver, copper gold magnesium, platinum, titanium and an alloy thereof. The organic solvent may include one of ethanol, propanol, methoxy propanol, ethoxy propanol, propoxy propanol, butoxy propanol, propane diol, dodecan glycol and benzyl alcohol. However, the organic solvent is not limited thereto and various other solvents may be used. Surfactant may be added to the organic solvent so that the screen printing method can be performed and the organic solvent can have certain viscosity to maintain its shape without falling down after being patterned. Then, the metal thin film forming material coated on the substrate 100 is heated at a certain temperature and thus dried. At this time, the organic solvent mixed with the metal nano particles is vaporized and thus removed and only the metal is attached on the substrate 100. Therefore, as illustrated in FIG. 3, the metal thin film pattern 200 is formed on the substrate 100. Conditions for the heat treatment may be changed according to kinds of the organic solvent and the metal nano particle. However, the heat treatment may be performed at a temperature lower than approximately 150° C. In the first embodiment, the screen printing method is used to coat the metal thin film forming material having the paste or solution type so as to form the metal thin film pattern 200. However, it is not limited thereto and any one of a pen printing method, a roller printing method and a gravure printing method may be used. Furthermore, the metal thin film pattern 200 may be formed using a deposition method such as a heat deposition method, a physical deposition method and an electron beam deposition method.

Referring to FIG. 4, a transparent electrode layer 300b is formed over the substrate 100 where the metal thin film pattern 20 is formed through a sputtering process. Of course, the transparent electrode layer 300b may be formed by performing various deposition processes in addition to the sputtering process according to kinds of transparent conducting materials used to form the transparent electrode layer 300b. Herein, the transparent electrode layer 300b is formed to have a thickness of approximately 150 nm to approximately 200 nm and sheet resistance that is equal to or lower than 15Ω. The transparent conducting material may include one of indium tin oxide (ITO), indium zinc oxide (IZO), zinc oxide (ZnO) and In₂O₃. In this embodiment, the transparent conducting material uses ITO.

Then, as illustrated in FIG. 5, a part of the transparent electrode layer 300b is removed through a laser scribing process, so that the transparent electrode pattern 300a is formed. Herein, the transparent electrode pattern 300a is disposed corresponding to the metal thin film pattern 200 that is disposed under the transparent electrode pattern 300a and a width of the transparent electrode pattern 300a is greater than that of the metal thin film pattern 200 so that the transparent electrode pattern 300a covers the metal thin film pattern 200.

In case of forming the transparent electrode pattern 300a by patterning the transparent electrode layer 300b through the laser scribing process, an edge part of the transparent electrode pattern 300a may be deformed by the high heat and a high energy occurring during the laser scribing process. Therefore, an insulating protection layer 400 is formed in an edge region of the transparent electrode pattern 300a to cover the edge part of the transparent electrode pattern 300a as described in FIG. 6. Namely, the insulating protection layer 400 is formed on an edge region of a top surface of the transparent electrode pattern 300a and a sidewall region of the transparent electrode pattern 300a. Moreover, the insulating protection layer 400 is also formed on a portion of the substrate 100 where the transparent electrode layer 300b is removed. As a result, although a part of the transparent electrode pattern 300a is damaged during the laser scribing process, it does not affect a characteristic of an electro-optic device. Herein, the insulating protection layer 400 may be formed through a deposition and printing method. In this embodiment, the insulating protection layer 400 is formed using the screen printing method. Although it is not shown, a stencil mask opening the edge region and the sidewall region of the transparent electrode pattern 300a is disposed on the substrate 100. After then, an insulating coating material is coated on the stencil mask. By moving a coating material on the stencil mask using a squeeze, the insulating coating material is coated on the edge region and the sidewall region of the transparent electrode pattern 300a that are exposed by the stencil mask. Through this, the insulating coating material is not coated on a central region of the transparent electrode pattern 300a where an electro-optic device pattern is formed. Subsequently, after removing the stencil mask, the insulating protection layer 400 is formed by emitting heat or light to thereby harden the insulating coating material. Herein, the material for the insulating protection layer 400 has a solution or paste type and may be a light hardening material or a heat hardening material. The material for the insulating protection layer 400 may include an organic material such as photo-resist or an inorganic material such as a nitride or an oxide like Al₂O₃. However, it is not limited thereto. The insulating protection layer 400 may be formed using a deposition method. At this point, the material for the insulating protection layer 400 uses one of an inorganic material and an organic material that arc able to be deposited and insulating. The method for depositing the insulating protection layer 400 may include an ion beam deposition method, an electron beam deposition method, a plasma beam deposition method or a chemical vapor deposition method.

FIGS. 7 to 9 describe the method for manufacturing the organic light emitting device in accordance with the first embodiment of the present invention.

Referring to FIG. 7, a lower electrode 210 and the insulating protection layer 400 are formed over the substrate 100. Herein, the lower electrode 210 includes the metal thin film pattern 200 formed on the substrate 100 and the transparent electrode pattern 300a formed to cover the metal thin film pattern 200. The metal thin film pattern 200, the transparent electrode pattern 300a and the insulating protection layer 400 are formed through the above-mentioned processes. ITO is used for the transparent electrode pattern 300a. Then, as described in FIG. 8, an organic material layer 500 is formed on the transparent electrode pattern 300a. Herein, the organic material layer 500 includes a hole injection layer 501, a hole transport layer 502, a light emitting layer 503 and an electron transport layer 504. It is preferable that the hole injection layer 501, the hole transport layer 502, the light emitting layer 503 and the electron transport layer 504 are sequentially stacked to form the organic material layer 500. That is, the hole injection layer 501 is formed on the transparent electrode pattern 300a using any one of CuPc. 2-TNATA and MTDATA. Then, the hole transport layer 502 is formed on the hole injection layer 501 using a material, which can effectively transport holes, such as NPB and TPD. The light emitting layer 503 is formed on the hole transport layer 502. The light emitting layer 503 may use a material having an excellent light emitting characteristic such as a green light emitting layer including Alq₃:C545T, a blue light emitting layer including DPVBi, a red light emitting layer including CBP:Ir (acac) and a combination thereof. After then, the electron transport layer 504 is formed on the light emitting layer 503 using a material such as Alp₃ and Bebq₂. At this point, the organic material layer 500 is formed through a heat deposition method.

Referring to FIG. 9, an upper electrode 600 is formed on the organic material layer 500. In this embodiment, since the metal thin film pattern 200 is disposed under the transparent electrode pattern 300a, the light generated at the light emitting layer 503 cannot be emitted toward the transparent electrode pattern 300a. Therefore, as shown in FIG. 9, the organic light emitting device in accordance with this embodiment is manufactured using a top emission scheme where the light is emitted toward the upper electrode 600. Thus, the upper electrode 600 disposed on the organic material layer 500 is formed to emit the light by depositing a metal such as LiF—Al. Mg:Ag and Ca—Ag having a thickness that is equal to or lower than dozens of micrometers. Although it is not shown, an encapsulation substrate where a sealant is coated is disposed over the upper electrode 600 and the encapsulation substrate is attached to the substrate 100 for the sealing. Herein, the encapsulation substrate may be formed of a light emitting material.

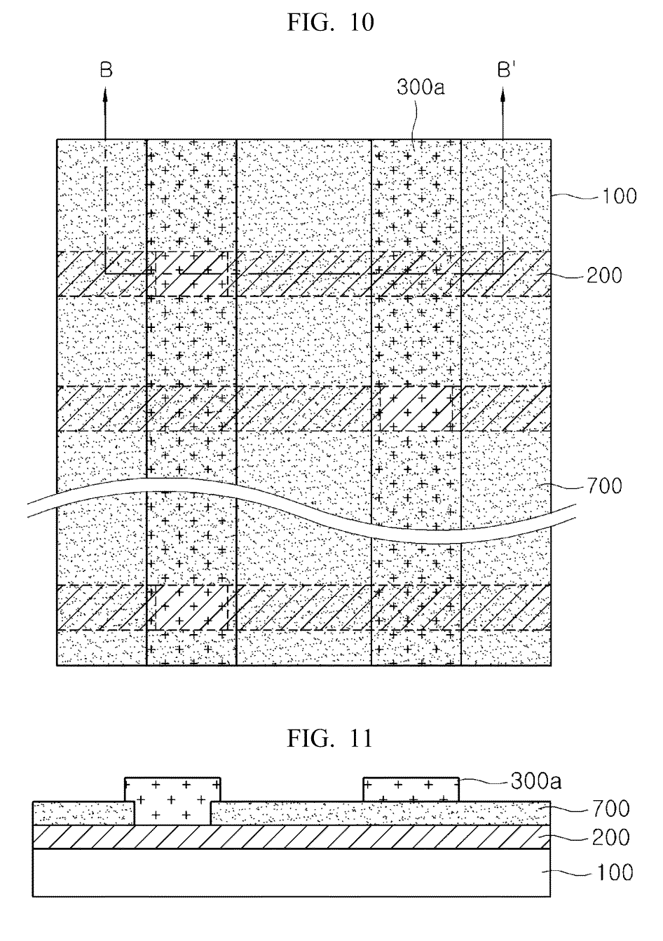

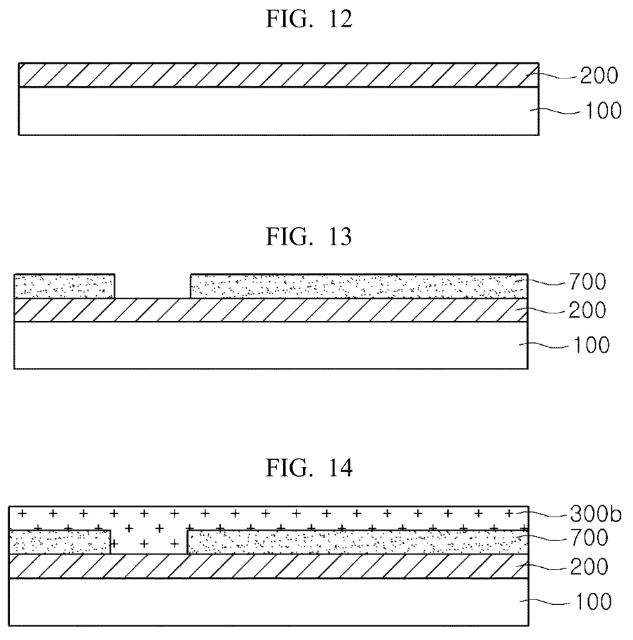

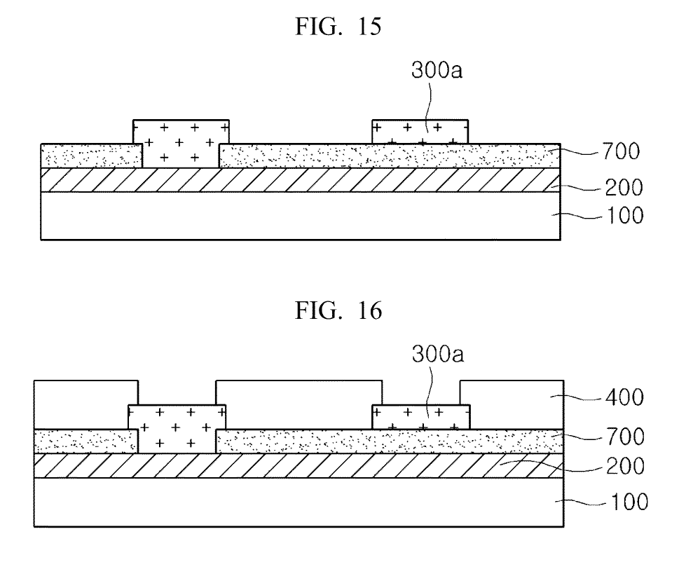

FIG. 10 illustrates a plan view of a transparent electrode in accordance with a second embodiment of the present invention. FIG. 11 illustrates a cross-sectional view obtained by cutting FIG. 10 along a line B-B′. FIGS. 12 to 16 illustrate cross-sectional views of a method for forming the transparent electrode in accordance with the second embodiment of the present invention. Hereinafter, the explanation overlapping with that of the first embodiment will be omitted.

Referring to FIGS. 10 and 11, the transparent electrode includes a plurality of metal thin film patterns 200 formed over a substrate 100, an insulating layer 700 partially exposing the top of the metal thin film patterns 200 as covering the top, a plurality of transparent electrode patterns 300a intersecting with the metal thin film patterns 200. Herein, the insulating layer 700 is disposed between the metal thin film patterns 200 and the transparent electrode patterns 300a to limit the connection between the metal thin film patterns 200 and the transparent electrode patterns 300a. As described in FIG. 10, the plurality of transparent electrode patterns 300a is formed on each of the metal thin film patterns 200 to intersect with the metal thin film patterns 200. For instance, in one of the metal thin film patterns 200, at least one of the transparent electrode patterns 300a intersecting with the metal thin film patterns 200 is connected to the metal thin film pattern 200 and at least one of the transparent electrode patterns 300a is connected to the insulating layer 700. Therefore, if a supply voltage is provided to one side of one of the metal thin film patterns 200, a current is transported to only the transparent electrode patterns 300a connected to the metal thin film pattern 200 where the supply voltage is inputted. Like this, since the connection between the metal thin film patterns 200 and the transparent electrode patterns 300a is limited by the insulating layer 700, the current may be selectively supplied to desired transparent electrode patterns 300a. Furthermore, under each of the transparent electrode patterns 300a, a plurality of metal thin film patterns 200 is formed to intersect with the transparent electrode pattern 300a. Thus, it is possible to prevent a voltage drop from occurring in the transparent electrode patterns 300a. That is, each transparent electrode pattern 300a is connected to its corresponding metal thin film pattern 200 having low resistance at two or more points and thus it is possible to prevent the voltage drop from occurring in the transparent electrode pattern 300a by providing the supply voltage to the metal thin film patterns 200 connected to the transparent electrode pattern 300a.

FIGS. 12 to 16 describe the method for forming the transparent electrode in accordance with the second embodiment of the present invention.

Referring to FIG. 12, the metal thin film pattern 200 is formed over the substrate 100. Herein, the metal thin film pattern 200 is formed by coating a metal thin film forming maternal having a paste or solution type on the substrate 100 through a screen printing method and then performing a heat treatment on the coated material at a given temperature.

Referring to FIG. 13, the insulating layer 700 is formed on the metal thin film pattern 200 formed over the substrate 100. The insulating layer 700 is formed to cover the metal thin film pattern 200 so that a part of the metal thin film pattern 200 is exposed as described in FIG. 13. The insulating layer 700 may be formed through a deposition and printing method. In this embodiment, the insulating layer 700 is formed using a screen printing method. Herein, the material for the insulating layer 700 has a solution or paste type and may be a light hardening material or a heat hardening material. In this embodiment, the insulating layer 700 uses the same material as that of the insulating protection layer described above.

Referring to FIG. 14, a transparent electrode layer 300b is formed on the metal thin film pattern 200 and the insulating layer 700 using a sputtering process. Then, as shown in FIG. 15, the transparent electrode pattern 300a is formed by patterning the transparent electrode layer 300b through a laser scribing process. At this point, as illustrated in FIG. 10, the transparent electrode pattern 300a is formed to orthogonally intersect with the metal thin film pattern 200. Moreover, the transparent electrode layer 300b is patterned to include a region where the insulating layer 700 is disposed between the metal thin film pattern 200 and the transparent electrode pattern 300a and a region where the metal thin film pattern 200 is connected with the transparent electrode pattern 300a. Through these processes, as described in FIG. 15, the transparent electrode pattern 300a disposed in a region corresponding to a region where the insulating layer 700 is not formed on the metal thin film pattern 200 among a plurality of transparent electrode patterns is connected to the metal thin film pattern 200. The transparent electrode pattern 300a disposed in a region corresponding to a region where the insulating layer 700 is formed on the metal thin film pattern 200 is not connected to the metal thin film pattern 200.

Referring to FIG. 16, an insulating protection layer 400 is formed on an edge region of a top surface of the transparent electrode pattern 300a and a sidewall region of the transparent electrode pattern 300a by coating an insulating material using a screen printing method. Furthermore, the insulating protection layer 400 is also formed on the insulating layer 700. Although it is not shown, an organic light emitting device of a top emission scheme is manufactured by forming an upper electrode and an organic material layer on the transparent electrode pattern 300a.

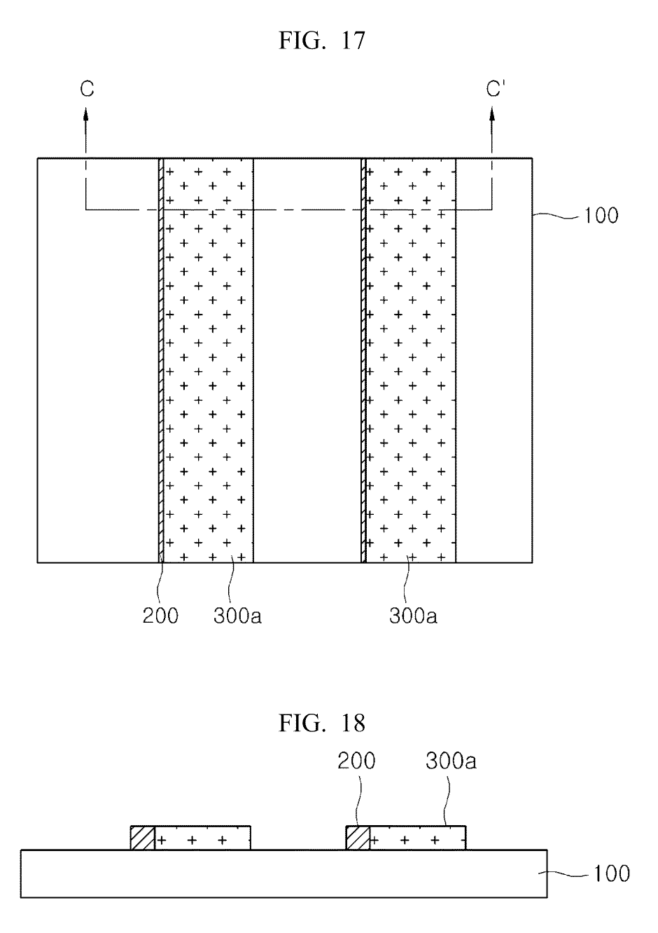

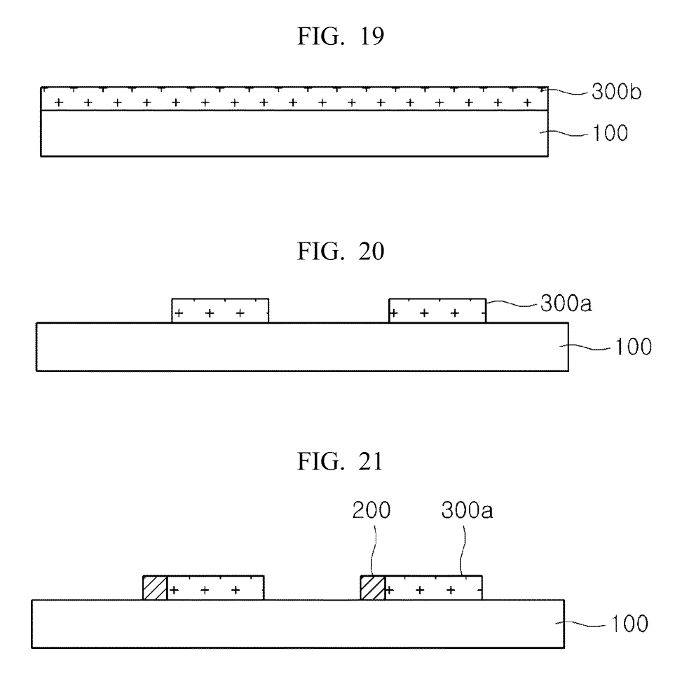

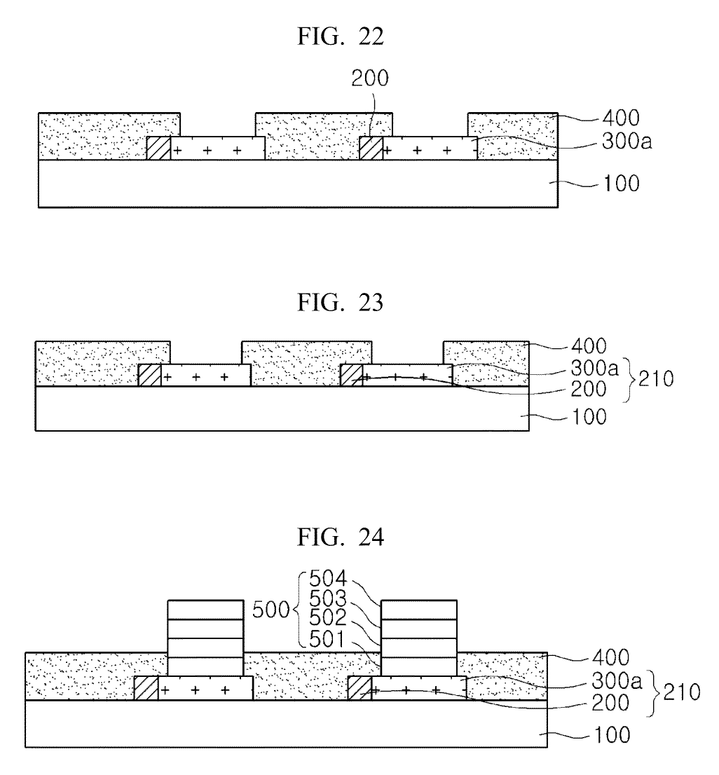

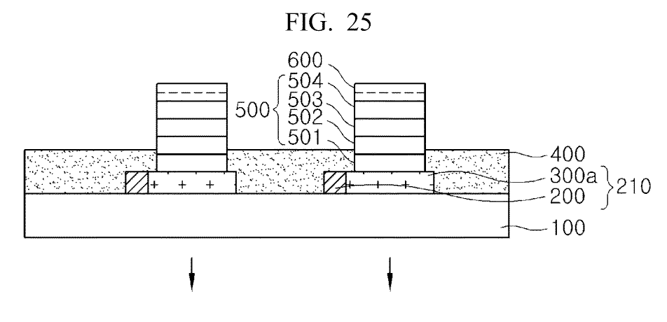

FIG. 17 illustrates a plan view of a transparent electrode in accordance with a third embodiment of the present invention. FIG. 18 illustrates a cross-sectional view obtained by cutting FIG. 17 along a line C-C′. FIGS. 19 to 22 illustrate cross-sectional views of a method for forming the transparent electrode in accordance with the third embodiment of the present invention. FIGS. 23 to 25 illustrate cross-sectional views of a method for manufacturing an organic light emitting device in accordance with the third embodiment of the present invention. Hereinafter, the explanation overlapping with those of the first and second embodiments will be omitted.

Referring to FIGS. 17 and 18, the transparent electrode includes a transparent electrode pattern 300a formed over a substrate 100 and a metal thin film pattern 200 formed on a sidewall of the transparent electrode pattern 300a. Herein, the metal thin film pattern 200 is formed corresponding to the transparent electrode pattern 300a on the sidewall of the transparent electrode pattern 300a. Through this, if a supply voltage is provided to one side of the metal thin film pattern 200 formed on the sidewall of the transparent electrode pattern 300a, a current flowing through the metal thin film pattern 200 having low resistance is transported to the whole transparent electrode pattern 300a.

Referring to FIGS. 19 to 22, the method for forming the transparent electrode in accordance with the third embodiment of the present invention is described.

Referring to FIG. 19, a transparent electrode layer 300b is formed over the substrate 100 through a sputtering process. As illustrated in FIG. 20, the transparent electrode pattern 300a is formed by patterning the transparent electrode layer 300b through a laser scribing process. Then, as shown in FIG. 21, the metal thin film pattern 200 is formed on the sidewall of the transparent electrode pattern 300a using a screen printing method. The metal thin film pattern 200 is formed on the sidewall of the transparent electrode pattern 300a to correspond to the transparent electrode pattern 300a. Further, the metal thin film pattern 200 is formed to have a width that is approximately 1/10 to 1/100 of that of the transparent electrode pattern 300a.

Referring to FIG. 22, an insulating protection layer 400 is formed on an edge region of a top surface of the transparent electrode pattern 300a and a sidewall region of the transparent electrode pattern 300a using a screen printing method. In this embodiment, the insulating protection layer 400 is formed on the top and a sidewall of the metal thin film pattern 200.

Referring to FIGS. 23 to 25, the method for manufacturing the organic light emitting device in accordance with the third embodiment of the present invention will be described.

Referring to FIG. 23, a lower electrode 210 and the insulating protection layer 400 are formed over the substrate 100. Herein, the lower electrode 210 includes the transparent electrode pattern 300a formed over the substrate 100 and the metal thin film pattern 200 formed on the sidewall of the transparent electrode pattern 300a. The metal thin film pattern 200, the transparent electrode pattern 300a and the insulating protection layer 400 are formed as described in FIGS. 19 to 22. The transparent electrode pattern 300a includes ITO. In this embodiment, since the metal thin film pattern 200 is connected with the sidewall of the transparent electrode pattern 300a, the organic light emitting device is manufactured to have a backlit scheme where light is emitted toward the transparent electrode pattern 300a. That is, as illustrated in FIG. 24, an organic material layer 500 is formed on the transparent electrode pattern 300a. Herein, the organic material layer 500 includes a hole injection layer 501, a hole transport layer 502, a light emitting layer 503 and an electron transport layer 504 that are sequentially stacked. Then, as illustrated in FIG. 25, an upper electrode 600 is formed on the organic material layer 500. At this point, the upper electrode 600 is formed by depositing a metal such as LiF—Al, Mg:Ag and Ca—Ag so that it can reflect light. Although it is not shown, an encapsulation substrate where a sealant is coated is disposed over the upper electrode 600 and the encapsulation substrate is attached to the substrate 100 for the sealing. Herein, the encapsulation substrate may be fabricated with one of a metal and a light permeable plate.

As described above, in accordance with the present invention, a uniform current can flow through the transparent electrode pattern by forming the metal thin film pattern to be connected and correspond to the transparent electrode pattern and providing the supply voltage to the metal thin film pattern. Thus, it is possible to manufacture an electro-optic device having uniform luminance.

Furthermore, the connection between the metal thin film pattern and the transparent electrode pattern is limited by the insulating layer that is formed to expose a portion of the metal thin film pattern. As a result, it is possible to drive the electro-optic device by selectively providing a current to the desired transparent electrode pattern without using a separate switching device.

Although the organic light emitting device has been described with reference to the specific embodiments, they are not limited thereto. The present invention can be applied to various electro-optic devices using a transparent electrode pattern. It will be readily understood by those skilled in the art that various modifications and changes can be made thereto without departing from the spirit and scope of the present invention defined by the appended claims.

What is claimed is:

1. An electro-optic device, comprising:
a substrate;
a metal thin film pattern formed on the substrate; and
a transparent electrode pattern formed to cover the metal thin film pattern, wherein one side of the metal thin film pattern is formed to be exposed to the outside of the transparent electrode pattern.

2. An electro-optic device, comprising:
a substrate;
a plurality of metal thin film patterns formed on the substrate;
a plurality of transparent electrode patterns formed to intersect with the plurality of metal thin film patterns; and
an insulating layer disposed between the metal thin film patterns and the transparent electrode patterns to expose portions of the metal thin film patterns.

3. An electro-optic device, comprising:
a substrate:
a metal thin film pattern formed on the substrate; and
a transparent electrode pattern connected to a sidewall of the metal thin film pattern and corresponding to the metal thin film pattern

4. The electro-optic device of any one of claims 1, wherein an insulating protection layer formed on a sidewall region and an edge region of a top surface of the transparent electrode pattern or the metal thin film pattern.

5. The electro-optic device of any one of claims 2, wherein an insulating protection layer formed on a sidewall region and an edge region of a top surface of the transparent electrode pattern or the metal thin film pattern.

6. The electro-optic device of any one of claims 3, wherein an insulating protection layer formed on a sidewall region and an edge region of a top surface of the transparent electrode pattern or the metal thin film pattern.

7. The electro-optic device of claim 2, wherein the transparent electrode patterns are connected to the metal thin film patterns through the exposed portions of the metal thin film patterns.

8. The electro-optic device of claim 2, wherein the plurality of metal thin film patterns intersects with the plurality of transparent electrode patterns and one transparent electrode pattern is connected to its corresponding metal thin film pattern at two or more points that are separated from each other.

10. The electro-optic device of claim 3, wherein the metal thin film pattern has a width that is approximately 1/10 to approximately 1/100 of a width of the transparent electrode pattern.

11. A method for manufacturing an electro-optic device, the method comprising:
forming a metal thin film pattern on a substrate; and
forming a transparent electrode pattern that is connected to the metal thin film pattern using a laser scribing process.

12. The method of claim 11, further comprising forming an insulating protection layer on a sidewall region and an edge region of a top surface of the transparent electrode pattern or the metal thin film pattern.

13. The method of claim 11, before forming the transparent electrode pattern, further comprising forming an insulating layer to expose a portion of the metal thin film pattern.

14. The method of claim 11, wherein the metal thin film pattern is formed using one selected from a group consisting of silver, copper, gold, magnesium, platinum, titanium and an alloy thereof, which has a solution or paste type.

15. The method of claim 14, wherein the metal thin film pattern is formed using one of a screen printing method, a pen printing method, a roller printing method and a gravure printing method.

16. A method for driving an electro-optic device comprising a metal thin film pattern disposed on a substrate and a transparent electrode pattern connected to the metal thin film pattern, the method comprising providing a supply voltage to a metal thin film pattern connected to a transparent electrode pattern.

17. The method of claim 16, wherein a current is selectively transported to the transparent electrode pattern connected to the metal thin film pattern by providing the supply voltage to the metal thin film pattern.
